(19) United States
(12) Patent Application Publication
(10) Pub. No.: US 2012/0236510 A1
(43) Pub. Date: Sep. 20, 2012

(54) APPARATUS FOR MANAGING HEAT DISTRIBUTION IN AN OSCILLATOR SYSTEM

(75) Inventor: Chih Wei Wong, Irvine, CA (US)

(73) Assignee: Navman Wireless OEM Solutions LP, Foothill Ranch, CA (US)

(21) Appl. No.: 13/051,946

(22) Filed: Mar. 18, 2011

(51) Int. Cl. H05K 7/02; H05K 3/30

(52) U.S. Cl. 361/748; 29/832

(57) ABSTRACT

A system and method of making an apparatus for managing heat distribution in an oscillator system is disclosed. In an example embodiment, the apparatus includes a resonator configured to provide a periodic signal, a circuit coupled to the resonator configured to compensate for changes in the periodic signal due to variation in temperature, and further includes a heat source configured to generate heat that heats the resonator and the circuit. At least one of the resonator, circuit, and heat source is embedded in a substrate, and the resonator, circuit, and heat source are arranged to heat the resonator and circuit substantially the same amount.

### TECHNICAL FIELD

This invention relates generally to thermal management in electronic circuits, and more specifically to methods and apparatus for distributing heat in an oscillator system.

### BACKGROUND OF THE INVENTION

Historically, electronic communications systems have relied upon precise clock signals. Without precise clocks, communications systems may be inefficient or even inoperable. One example is the global positioning system (GPS), a space-based system which employs communications signals from satellites to provide location and time information to terrestrial receivers. A GPS receiver uses phase, frequency, and time information from radio frequency signals broadcast by satellites to determine the signals' travel time. A very high precision and high performance clock is used to minimize its Time To First Fix (TTFF) and to maximize performance especially in weak-signal environments. If the clock deviates from a predetermined frequency, then errors in the GPS receiver's calculations will propagate and grow. Other communications systems, including mobile telephone handsets, wireless local area networks (WLANs), wireless broadband, and base stations, also need high precision clocks.

Performance of electronic circuits may vary over temperature, including electronic components/devices in portable communications devices. Piezoelectric crystal oscillators, for example, may be used to generate precision clocks in communications systems, but the piezoelectric crystal's frequency may depend on the temperature. Electronic systems may not only absorb heat from their environment, but also produce heat themselves. Current flowing through active and passive electrical components results in power dissipation and increased temperatures. Greater integration and higher clock speeds result in greater heat generation. This temperature variability in electronic systems may adversely affect the clock signals generated by piezoelectric crystal oscillators and hence the operation of the whole system. Accordingly, there is a need to reliably generate precision clock signals over a range of temperatures.

### BRIEF DESCRIPTION OF THE DRAWINGS

FIG. 1 is a simplified block diagram of an electronic system.

FIG. 2 is a simplified cross-sectional view of an electronic system according to some embodiments of the present invention.

FIG. 3 is a simplified cross-sectional view of an electronic system according to some embodiments of the present invention.

FIG. 4 is a simplified cross-sectional view of an electronic system according to some embodiments of the present invention.

FIG. 5 is a simplified cross-sectional view of a substrate according to various embodiments of the present invention.

FIG. 6 is a simplified functional block diagram of a wireless device.

In the figures, elements having the same designation have the same or substantially similar function. The figures are illustrative only and relative sizes and distances depicted in the figures are for convenience of illustration and have no further meaning.

### DETAILED DESCRIPTION OF THE INVENTION

In the following description, certain details are set forth below to provide a sufficient understanding of the invention. However it will be clear to one skilled in the art that the invention may be practiced without these particular details. In other instances, well-known circuits, control signals, timing protocols, and software operations have not been shown in detail or omitted entirely in order to avoid unnecessarily obscuring the invention.

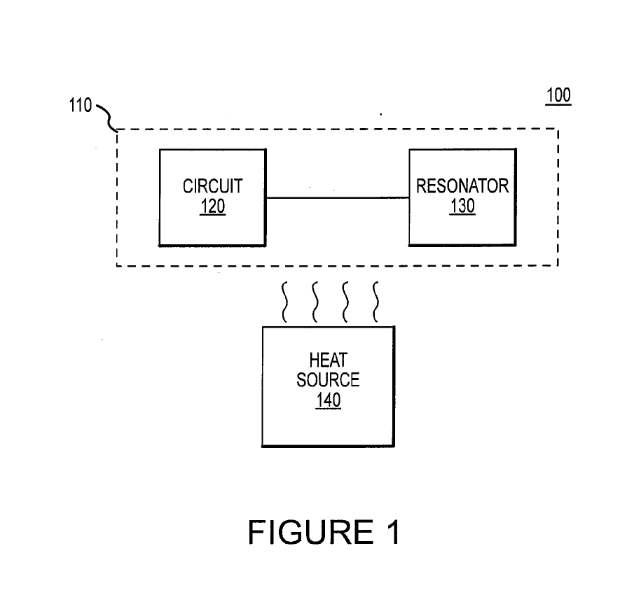

FIG. 1 is a simplified block diagram of an electronic system 100 comprising a circuit 120, resonator 130, and heat source 140. Circuit 120 and resonator 130 together may be referred to as an oscillator 110. In operation, circuit 120 may apply a voltage to resonator 130, causing resonator 130 to change its shape. When circuit 120 removes the voltage, resonator 130 may generate a voltage as it returns to its previous shape. Circuit 120 may repeat and maintain this process (i.e., resonator's 130 oscillations) by amplifying the voltage from resonator 130 and feeding it back to resonator 130. Circuit 120 may convert the oscillation (pulses) from resonator 130 into signals (e.g., clock signals) suitable for analog and digital circuits. For example, oscillator 110 accuracy may be from 5 PPM to 0.1 PPM. In some embodiments, oscillator 110 has a 0.5 PPM accuracy. As another example, resonator 130 may be a piezoelectric crystal resonator. In various embodiments, resonator 130 is a quartz crystal resonator. In other embodiments, resonator 130 is a microelectromechanical systems (MEMS) resonator.

Generally the frequency at which piezoelectric crystals oscillate will change with variations in temperature. For example, a crystal oscillator exactly on a predefined frequency (or range of frequencies) at 25° C. with a frequency variation of five parts per million (PPM) per degree Celsius change could experience a frequency offset of 25 PPM with only a 5° C. temperature rise. Since temperature effects on a crystal oscillator are, for the most part, consistent and reproducible, circuits may be designed to compensate for the temperature effects on oscillator frequency.

Circuit 120 may include circuitry to compensate for temperature variations. For example, circuit 120 may include a temperature sensor and compensation circuitry which may operate with resonator 130 over a predefined range of temperatures. Oscillator 110, for example, may have an operating temperature range of −40° C. to +85° C. In some embodiments, oscillator 110 has an operating range of −20° C. to +60° C. In operation, circuit 120 may use the compensation circuitry to compensate for temperature effects on the resonator 130.

Resonator 130 and circuit 120 (including temperature sensor and compensation network) together may form a temperature compensated crystal oscillator (TCXO). The compensation network may include capacitors, thermistors, compensating elements (e.g., in series), amplifiers, read only memories (ROMs), low dropout regulator (LDO), divider, and phase-lock-loop (PLL), as well as other circuit elements.

As another example, circuit 120 may include a temperature sensor and an oven controller. Circuit 120 may use the output of the temperature sensor to control an oven. An oven may include a heating element. In operation, resonator 130 may be maintained at a constant temperature, for example, by heating the resonator to a temperature above an expected ambient temperature (e.g., 15° to 20° above the highest temperature to which resonator 130 will likely be exposed). An oven may optionally include a thermally insulated container or enclosure around resonator 130. Resonator 130 and circuit 120 (including temperature sensor and oven controller) together may form an oven controlled crystal oscillator (OCXO).

Other combinations and permutations are possible without deviating from the scope of the invention. Resonator 130 and circuit 120 together, for example, may form a voltage-controlled crystal oscillator (VCXO), digitally-controlled crystal oscillator (DCXO), voltage controlled/temperature compensated crystal oscillator (VCTCXO), as well as other oscillator systems.

Heat source 140 may be one or more components in electronic system 100 which generate heat. Heat source 140, for example, may be a baseband processor for a portable wireless device (e.g., for use in a global positioning system, cellular network, wireless local area network, wireless wide area network, etc.). Heat generated by heat source 140 may affect the temperature of electronic system 100 and in particular the temperature of circuit 120 and resonator 130. Temperature compensation in TCXOs and OCXOs may operate properly when the temperature measured by circuit 120 is substantially the same as the temperature experienced by resonator 130. That is, the amount of compensation provided by circuit 120 for the temperature effect on resonator 130 is based at least on part on the measured temperature. The assumption is that the measured temperature is approximately the same as the temperature of the resonator 130. If the measured temperature, however, does not accurately reflect the temperature of the resonator 130, the compensation provided by the compensation circuit of circuit 120 will not effectively compensate for the temperature impact on the resonator 130. Hence, it is desirable for circuit 120 and resonator 130 to experience substantially the same temperature.

A different temperature between the circuit 120 and the resonator 130 may result, for example, when due to spatial arrangement circuit 120 receives more heat from heat source 140 than resonator 130, or resonator 130 receives more heat than circuit 120. Such an arrangement, for example, may occur when circuit 120, resonator 130, and heat source 140 are arranged on the same plane of a substrate (e.g., printed circuit board) and the circuit 120 and the resonator 130 are located at significantly different distances from the heat source 140.

To facilitate circuit 120 and resonator 130 being heated to substantially the same amount by the heat from heat source 140, embodiments of the present invention include at least one of the components (i.e., circuit 120, resonator 130, and heat source 140) embedded in a substrate onto which the other components may be attached. The other components may be arranged on the substrate in such a manner as to be heated substantially the same amount by the heat from heat source 140. Embodiments of the present invention may also result in a low profile (i.e., height of components attached to the substrate).

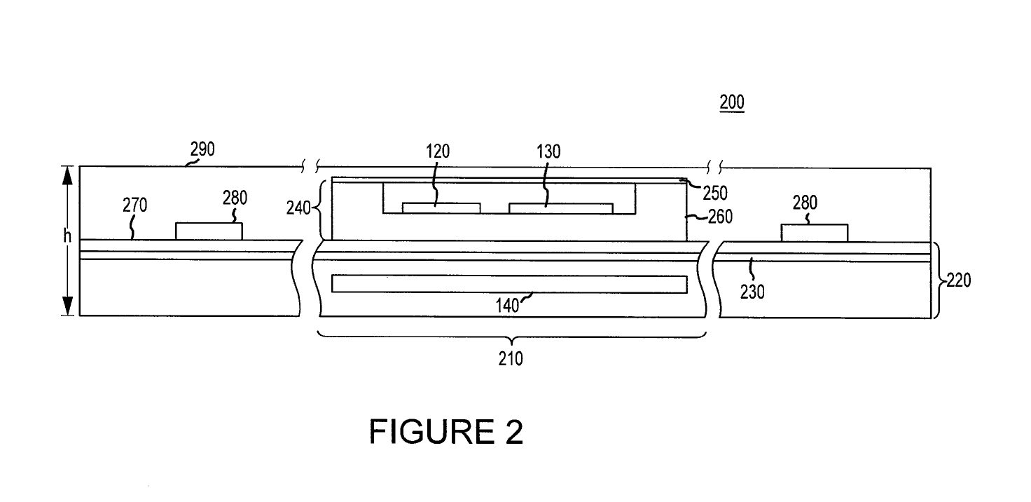

FIG. 2 illustrates an electronic system 200 according to some embodiments of the present invention. For clarity, the same reference numerals are used to designate elements analogous to those described above in connection with FIG. 1. For brevity, the description of FIG. 1 is not repeated with respect to FIG. 2. Coupled to a surface 270 of substrate 220 are package 240 and optionally electrical device(s) 280. Package 240 may include circuit 120 and resonator 130. Circuit 120 and resonator 130 are coupled to each other and to package 240. Heat source 140 may be embedded in substrate 220, as will be discussed further below. As depicted in FIG. 2, circuit 120 and resonator 130 may be arranged horizontally alongside one another (i.e., side by side) on package substrate 260. In some embodiments, circuit 120 and resonator 130 may be assembled into different packages.

Electrical devices 280 may be active and/or passive electrical components, such as resistors, capacitors, discrete semiconductors, small ICs, memory (e.g., dynamic random access memory (DRAM), FLASH memory, etc.), controllers (e.g., touch-screen controller), applications processors, accelerometers, compasses, as well as other components. Circuit 120 may be an integrated circuit (IC) in die form or an IC die assembled in a package. In some embodiments of the present invention, circuit 120 may be an IC die assembled into a chip scale package (CSP) or land grid array (LGA). Resonator 130 may be a piezoelectric crystal or a MEMS resonator mounted in a package such as an LGA.

Package 240 may include package substrate 260 and lid 250, which may optionally be hermetically sealed. Package 240 may be a multi-chip module (MCM) corresponding to an LGA form factor. Package 240 may also be a laminated MCM with encapsulant applied over circuit 120 and resonator 130 (which are positioned side-by-side in package 240), or a system-in-a-package (SiP) with circuit 120 and resonator 130 stacked vertically. Package 240 may also include underfill, thermal gel/paste, and the like. Substrate 260 may be ceramic. Substrate 260 may also be a multi-layer laminated printed circuit board (PCB). Lid 250 may be metal. Lid 250 may also be ceramic or epoxy/plastic, and may include an optional heat spreader.

In some embodiments where the resonator 130 is a MEMS device, resonator 130 may be stacked on the top of circuit 120 using die attach adhesive (not shown). Such a configuration may be referred to as “stacked die.” Interconnection and signal transfer between 130 and 120 may be through bond wires from the pads on 130 to the pads on 120 (not shown). Bond wires may also be used for interconnect and signal transfer from stacked die resonator 130 and circuit 120 to substrate 220. In some embodiments, the stacked die resonator 130 and circuit 120 are assembled in package 240 and package 240 is mounted to substrate 220 as described above. Other combinations and permutations are possible within the scope of the invention. Other packaging technologies may be used.

In practice, electronic system 200 may be a subassembly in a larger assembly (not shown). The surface 270 of substrate 220, devices 280, and package 240 may be covered by a metal lid or plastic/epoxy encapsulant 290. The metal lid or plastic/epoxy encapsulant 290 may facilitate handling of the electronic system 200 by automated manufacturing machines (e.g., pick and place machine) during assembly of the larger assembly. In some embodiments, the combined height h of substrate 220 and metal lid or plastic/epoxy encapsulant 290 may be 1 mm or less. For example, substrate 220 may be 400 μm or less thick, and package 240 substantially covered by metal lid or plastic epoxy encapsulant 290 may be 400 μm or less tall, resulting in a combined height h of 1 mm or less. In some embodiments where resonator 130 is a MEMS resonator, package 240 may be omitted, and circuit 120 and resonator 130 may be coupled to surface 270 of substrate 220, reducing height h further.

In operation, heat generated by heat source 140 spreads through printed circuit board 220. In some embodiments of the present invention, substrate 220 may include a heat conducting plane or layer 230 that may be disposed between heat source 140 and a surface 270 of substrate 220. The heat conducting plane or layer 230 may contribute to heat distribution in substrate 220. The heat conducting plane or layer 230 may be a layer of metal, such as copper, and may be substantially solid (with vias) or comprised of signal traces. Heat from heat source 140 may propagate through substrate 220 to package 240, and within package 240 to circuit 120 and resonator 130. Accordingly, circuit 120 and resonator 130 in package 240 may be positioned on a surface 270 of substrate 220 to be heated substantially the same amount by heat source 140 embedded within substrate 220.

For example, in some embodiments of the present invention, package 240 is approximately centered above heat source 140. In the embodiment illustrated with reference to FIG. 2, the package 240, which includes circuit 120 and resonator 130 therein, is positioned substantially over the heat source 140 so that the heat generated by the heat source 140 will heat both the circuit 120 and resonator 130 approximately the same. The circuit 120 and resonator 130 may be attached to the package 240 so that both components are approximately in the same horizontal plane. In some embodiments, the circuit 120 and resonator 130 are positioned within the package 240 so that the two are laterally disposed to one another and positioned relative to the heat source 140 within the package 240 to be heated substantially the same by the heat source 140. For example, the space/distance between the circuit 120 and the heat source 140 is substantially the same as the space/distance between the resonator 130 and the heat source 140. In some embodiments, the package 240 is located relative to the heat source 140 so that at least a portion of the package 240 is above the heat source 140. In other embodiments, the package 240 does not overlap (as viewed from above) any portion of the heat source 140, but positioned so that the circuit 120 and resonator 130 are heated substantially the same by the heat source 140.

As may be readily understood by one of ordinary skill in the art, different combinations and permutations are possible within the scope of the present invention. Assembly 210 is depicted in two dimensions such that package 240 may appear to be positioned along one dimension (i.e., left-right). However package 240 may be positioned in two dimensions over surface 270 of substrate 220. Package 240, for example, may be positioned on a surface 270 of substrate 220 off-center from heat source 140 embedded in substrate 220. Heat conducting plane 230 may transfer heat approximately uniformly on the same horizontal plane to both circuit 120 and resonator 130. It is desirable for the package 240 to be positioned so that circuit 120 and resonator 130 in package 240 are heated substantially the same amount by heat source 140.

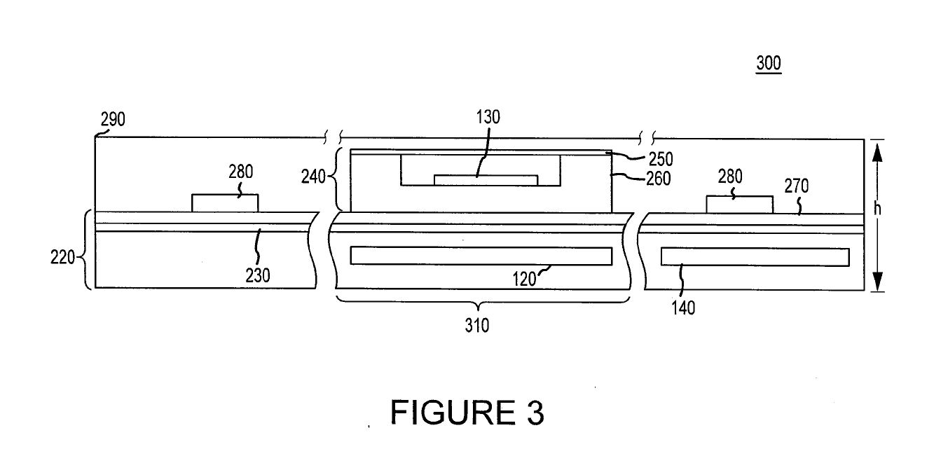

FIG. 3 depicts an electronic system 300 according to other embodiments of the present invention. For clarity, the same reference numerals are used to designate elements analogous to those described above in connection with FIGS. 1 and 2. For brevity, the description of FIGS. 1 and 2 are not repeated with respect to FIG. 3. Coupled to a surface 270 of substrate 220 are package 240 and optionally electrical devices 280. Package 240 may include resonator 130. Circuit 120 may be embedded in substrate 220.

Circuit 120, for example, may be an IC in die form or an IC die assembled in a package. In some embodiments of the present invention, circuit 120 may be an IC die assembled into a CSP or LGA. Resonator 130 may be a piezoelectric crystal mounted in package 240. Package 240 may be an LGA including package substrate 260 and lid 250, which may optionally be hermetically sealed. Other combinations and permutations are possible within the scope of the invention. For example, other packaging technologies may be used in place of or in addition to those described above. In other embodiments, resonator 130 may be a MEMS die coupled to surface 270 of substrate 220 and package 240 may be omitted.

Heat source 140, optional heat conducting plane 230, and metal lid or plastic/epoxy encapsulant 290 are analogous to that of FIG. 2 except as described below. For brevity, the description of FIG. 2 is not repeated with respect to FIG. 3. In operation, heat generated by heat source 140 spreads through printed circuit board 220. In some embodiments of the present invention, heat is distributed through substrate 220 with optional heat conducting plane 230. Heat from heat source 140 travels through substrate 220 to package 240, within package 240 to resonator 130, and to circuit 120 in substrate 220. Accordingly, circuit 120 in substrate 220 and resonator 130 in package 240 may be positioned relative to each other to be heated substantially the same amount by heat source 140 within substrate 220.

In some embodiments of the present invention, package 240 is approximately centered above circuit 120. Although shown in FIG. 3 as having the resonator 130 located in the package 240 and the circuit 120 embedded in the substrate 220, in other embodiments the circuit 120 may be located in the package 240 and the resonator 130 embedded in the substrate 220. As illustrated for the embodiment of FIG. 3, at least one of the circuit 120 or oscillator 130 is embedded in the substrate 220. Additionally, although the heat source 140 is illustrated in FIG. 3 as being embedded in the substrate 220, in some embodiments the heat source 140 may be coupled to the surface 270 of the substrate 220.

As can be readily understood by one of ordinary skill in the art, different combinations and permutations are possible within the scope of the present invention. For example, assembly 310 is depicted in two dimensions such that package 240 may appear to only be positioned along one dimension (i.e., left-right). However package 240 may be positioned in two dimensions over surface 270 of substrate 220. Package 240, for example, may be positioned on a surface 270 of substrate 220 off-center from circuit 120 embedded in substrate 220. Heat conducting plane 230 may transfer heat approximately uniformly on the same horizontal plane to both circuit 120 and resonator 130. It is desirable for the position of package 240 is that circuit 120 in substrate 220 and resonator 130 in package 240 be heated substantially the same amount by heat source 140.

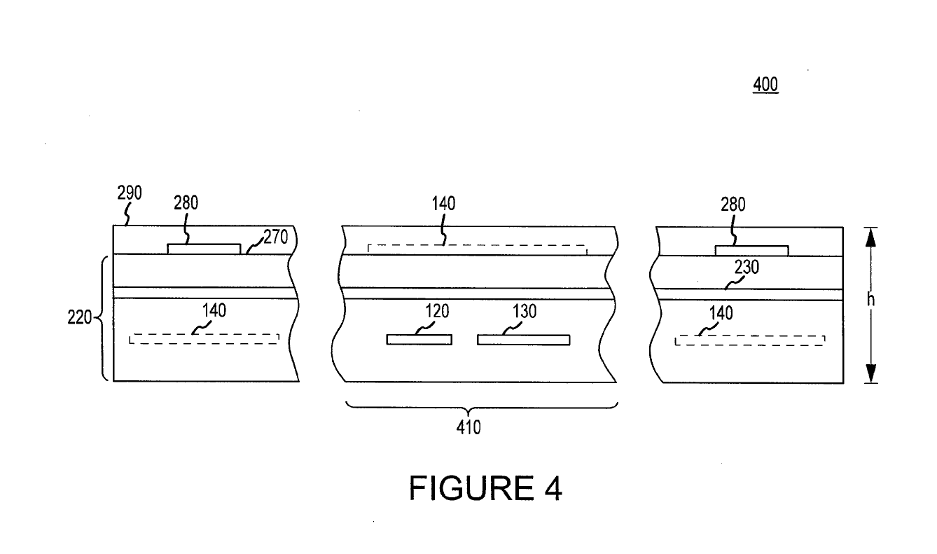

FIG. 4 depicts an electronic system 400 according to some embodiments of the present invention. For clarity, the same reference numerals are used to designate elements analogous to those described above in connection with FIGS. 1, 2, and 3. For brevity, the description of FIGS. 1, 2, and 3 are not repeated with respect to FIG. 3. Embedded in substrate 220 are circuit 120 and resonator 130. As depicted in FIG. 4, heat source 140 may be embedded in substrate 220 and/or coupled to surface 270 of substrate 220.

In operation, heat generated by heat source 140 may propagate through substrate 220 to circuit 120 and resonator 130. In some embodiments of the present invention, substrate 220 may include a heat conducting plane or layer 230 that may be disposed between heat source 140 and circuit 120 and resonator 130. The heat conducting plane or layer 230 may contribute to heat distribution in substrate 220. Accordingly, circuit 120 and resonator 130 may be positioned in substrate 220 to be heated substantially the same amount by heat source 140.

For example, in some embodiments of the present invention, circuit 120 and resonator 130 are approximately centered below heat source 140. In the embodiment illustrated with reference to FIG. 4, circuit 120 and resonator 130 are positioned substantially below heat source 140 so that the heat generated by the heat source 140 will heat both the circuit 120 and resonator 130 approximately the same. Circuit 120 and resonator 130 may be embedded in substrate 220 so that both components are approximately in the same horizontal plane. In some embodiments, the circuit 120 and resonator 130 are positioned within the package 240 so that the two are laterally disposed to one another and positioned relative to the heat source 140 in substrate 220 to be heated substantially the same by the heat source 140. For example, the space/distance between the circuit 120 and the heat source 140 is substantially the same as the space/distance between the resonator 130 and the heat source 140.

In embodiments of the present invention, circuit 120, resonator 130, and heat source 140 are embedded in substrate 220. Circuit 120, resonator 130, and heat source 140 may occupy the same horizontal plane. As depicted in FIG. 4, circuit 120, resonator 130, and heat source 140 may appear to be arranged in one dimension (left-right). However, circuit 120, resonator 130, and heat source 140 may be arranged in substrate 220 in two dimensions so that circuit 120 and resonator 130 are heated substantially the same amount by heat source 140. For example, the space/distance between the circuit 120 and the heat source 140 is substantially the same as the space/distance between the resonator 130 and the heat source 140. Heat conducting plane 230 may transfer heat approximately uniformly on the same horizontal plane to both circuit 120 and resonator 130.

As may be readily understood by one of ordinary skill in the art, different combinations and permutations are possible within the scope of the present invention. Assembly 410 is depicted in two dimensions such that heat source 140 may appear to be positioned along one dimension (i.e., left-right). However heat source 140 may be positioned in two dimensions over surface 270 of substrate 220. Heat source 140, for example, may be positioned on a surface 270 of substrate 220 off-center from circuit 120 and resonator 130 in substrate 220. Heat conducting plane 230 may transfer heat approximately unifomrly on the same horizontal plane to both circuit 120 and resonator 130. It is desirable for circuit 120 and resonator 130 in substrate 220 to be positioned so that circuit 120 and resonator 130 are heated substantially the same amount by heat source 140.

As another example, circuit 120 and heat source 140 may be included in the same integrated circuit die (not depicted). In some embodiments, the combined circuit 120 and heat source 140 work in conjunction with resonator 130. The combined circuit 120 and heat source 140 may be coupled to surface 270 of substrate 220 or embedded in substrate 220. Resonator 130 may also be coupled to surface 270 of substrate 220 or embedded in substrate 220. It is desirable for resonator 130 to be arranged so that circuit 120 (in the combined circuit 120 and heat source 140) and resonator 130 are heated substantially the same amount by heat source 140 (in the combined circuit 120 and heat source 140).

In some embodiments of the invention, the arrangement of the resonator 130 and the circuit 120 may result in an encapsulated package that has a lower profile compared to conventional arrangements, for example, the resonator 130 and circuit 120 stacked within the package 240 that is attached to a surface of the substrate 220. For example, the embodiment illustrated in FIG. 2 may have a lower profile due to the side-by-side arrangement of the resonator 130 and circuit 120 in the package 240. The embodiment illustrated in FIG. 3 may also have a lower profile resulting from having the resonator 130 (or circuit 120) disposed in the package 240 and the circuit 120 (or resonator 130) embedded in the substrate 220. Although not a requirement of the present invention, some embodiments may, however, provide the desirable benefit of a lower profile.

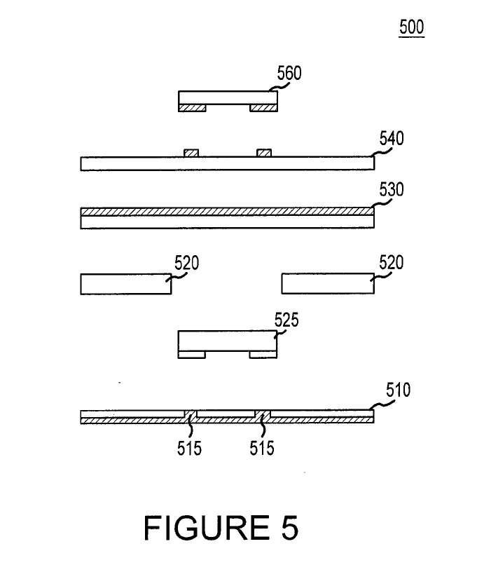

FIG. 5 illustrates a cross-sectional view of a simplified printed circuit board (PCB) stackup including embedded component(s) and conventionally mounted component(s). Embedded component 525 may be attached to first layer 510. First layer 510, second layer 520, third layer 530, and fourth layer 540 may be stacked and may be pressed/bonded together to form a substrate. Vias or bumps 515 may be formed and filled for electrical coupling to the inputs/outputs (I/Os) of embedded component 520. Metal foil on first layer 510 and fourth 540 layer may be patterned, etched, and plated. One or more conventionally mounted components 560 may be attached on the first layer 510 and/or fourth layer 540 using surface mount technology (SMT).

First layer 510, for example, may be a dielectric material with a layer of metal foil bonded on one side. Second layer 520 may be a dielectric material and may include a mechanically- and/or chemically-created opening for embedded component 525. Third layer 530 and fourth layer 530 may be a dielectric material having a thin layer of metal foil bonded on one side. The dielectric materials of the first layer 510, second layer 520, third layer 530, and fourth layer 540 may be cured (i.e., core) or uncured (i.e., prepreg) fiberglass-epoxy resin, such as FR-4, CEM, BT-Epoxy, polyimide, Teflon (polytetrafluoroethylene), and the like. The metal foil may be copper foil.

Various combinations and permutations may be used without deviating from the scope of the present invention. The substrate may have a different number of (metal) layers (e.g., 2-24 layers). In some embodiments of the present invention, the substrate includes six layers. Although only one embedded component 525 and one conventionally mounted component 560 are depicted in FIG. 5, different numbers of embedded components 525 and conventionally mounted components 560 may be included.

FIGS. 2-5 are simplified and offered by way of illustration only. As such, FIGS. 2-5 do not show particular terminal configurations or electrical connections to packages, substrates, or layers.

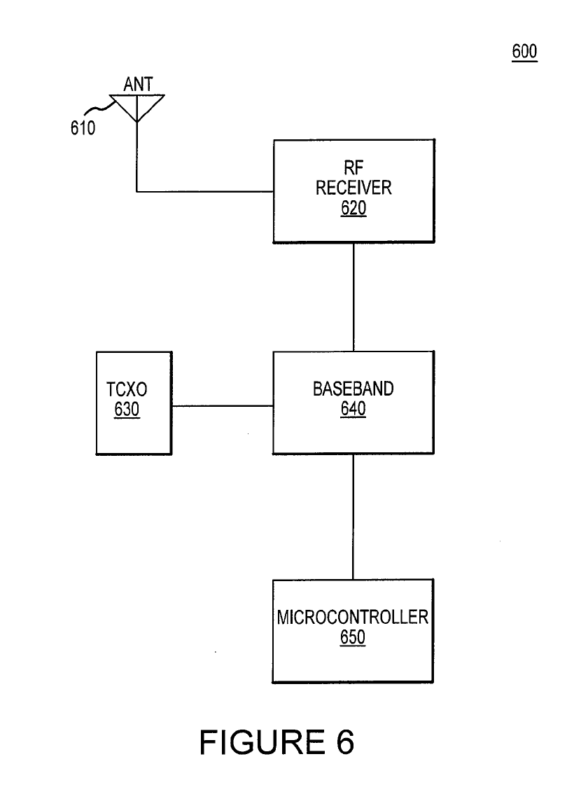

FIG. 6 illustrates a simplified functional block diagram of a portable wireless device 600. Portable wireless device 600 comprises an antenna block 610, radio frequency (RF) receiver/transmitter block 620, TCXO block 630, baseband and logic block 640, and microcontroller block 650. Antenna block 610 may be a transducer which transmits and receives electromagnetic waves and converts it into electric current. RF receiver/transmitter block 620 may receive the electric current from antenna block 610 and produce electrical signals based thereon, and/or drive electric current in antenna block 610. Baseband and logic block 640 may convert the analog signal from the RF receiver/transmitter block 620 to a digital signal (and vice-versa) and may perform application-specific processing of the digital signal (e.g., location determination in a GPS receiver, data decoding/encoding in a wireless networking device, sound/voice decoding/encoding in a cell phone, etc.). TCXO block 630 may provide a high-precision clock. Microcontroller block 550 may provide a user interface, and/or run applications.

Antenna block 610 may be designed for a specific frequency or range of frequencies. Antenna block 610 may be omnidirectional. RF receiver/transmitter, block 620 may include a low-noise amplifier (LNA), band-pass filter (BPF), and mixer. In some embodiments, RF receiver/transmitter block 620 includes only one of a receiver or transmitter (e.g., a GPS receiver may only include a receiver). Baseband and logic block 640 may include a digital signal processor (DSP), memory (e.g., SDRAM), memory management unit, input/output (I/O), and the like. TCXO block 630 may also, for example, be an OXCO and/or VCTCXO. In some embodiments, baseband and logic block 640 may be combined with a portion of the TCXO block on one integrated circuit die. In these embodiments, an oscillator (e.g., crystal or MEMS oscillator) may be used in conjunction with the one integrated circuit die. Microcontroller block 650 may include an interrupt controller, microcontroller, programmable I/O, etc. The microcontroller in microcontroller block 650 may be connected to the memory management unit in baseband and logic block 640.

From the foregoing, it will be appreciated that, although specific embodiments of the invention have been described herein for purposes of illustration, various modifications may be made without deviating from the spirit and scope of the invention. Such modifications are well within the skill of those ordinarily skilled in the art. Accordingly, the invention is not limited except as by the appended claims.

What is claimed is:

1. An apparatus comprising:
a substrate;
a resonator configured to provide a periodic signal;
a circuit coupled to the resonator, the circuit configured to compensate for changes in the periodic signal due to variation in temperature; and
a heat source configured to generate heat that heats the resonator and the circuit, at least one of the resonator, circuit, and heat source is embedded in the substrate, the resonator and circuit positioned relative to the heat source to be heated substantially the same amount by the heat generated by the heat source.

2. The apparatus of claim 1, further comprising electrical components coupled to a surface of the substrate, wherein the substrate is a printed circuit board (PCB).

3. The apparatus of claim 1 wherein the heat source is embedded in the substrate.

4. The apparatus of claim 1 wherein the circuit is embedded in the substrate.

5. The apparatus of claim 1 wherein the circuit and the heat source comprise one integrated circuit.

6. The apparatus of claim 1 wherein the resonator is embedded in the substrate.

7. The apparatus of claim 1 wherein the resonator is a crystal oscillator.

8. The apparatus of claim 1 wherein the resonator is a microelectromechanical systems (MEMS) resonator.

9. The apparatus of claim 8 wherein the resonator and the circuit are configured as stacked die.

10. The apparatus of claim 1 wherein the resonator is coupled to a surface of the substrate.

11. An apparatus comprising:
a substrate; and
a package coupled to a surface of the substrate, the package including a resonator configured to provide a periodic signal and a circuit configured to compensate for changes in the periodic signal due to variation in temperature, wherein the resonator and the circuit are arranged side by side.

12. The apparatus of claim 11 further comprising a heat source embedded in the substrate and configured to generate heat, the heat source positioned relative to the package to heat the resonator and circuit substantially the same amount with the heat generated by the heat source.

13. The apparatus of claim 12 wherein the package is located on the surface substantially over the heat source embedded in the substrate.

14. The apparatus of claim 11 wherein the substrate includes a heat conducting layer configured to distribute heat through the substrate.

15. The apparatus of claim 14 wherein the heat conductive layer is disposed between the heat source and the package.

16. The apparatus of claim 11 wherein the package comprises a ceramic package.

17. The apparatus of claim 11 further comprising encapsulant, the encapsulant configured to cover at least a portion of the surface and the package.

18. The apparatus of claim 11 wherein the resonator is a quartz crystal.

19. The apparatus of claim 11 wherein the resonator is a MEMS resonator.

20. The apparatus of claim 11 wherein the heat source is an integrated circuit.

21. An apparatus comprising:
a substrate;
a package coupled to a surface of the substrate, the package including a resonator, the resonator configured to provide a periodic signal; and
a circuit embedded in the substrate and coupled to the resonator, the circuit configured to compensate for changes in the periodic signal due to variation in temperature.

22. The apparatus of claim 21, further comprising a heat source, wherein the package is arranged on the surface and the circuit is arranged in the substrate to receive substantially the same amount of heat from the heat source.

23. The apparatus of claim 22 wherein the heat source is embedded in the substrate.

24. The apparatus of claim 22 wherein the circuit and the heat source comprise one integrated circuit.

25. The apparatus of claim 24 wherein the one integrated is embedded in the substrate.

26. The apparatus of claim 22 wherein the heat source is laterally disposed from the package and circuit.

27. The apparatus of claim 21, wherein the package is located substantially over the circuit embedded in the substrate.

28. The apparatus of claim 21 wherein the package is a ceramic package.

29. The apparatus of claim 21 further comprising encapsulant, the encapsulant configured to cover the surface and the package.

30. The apparatus of claim 21 wherein the resonator is a quartz crystal.

31. The apparatus of claim 21 wherein the resonator is a MEMS resonator.

32. The apparatus in claim 21 wherein the heat source is an integrated circuit.

33. A portable device comprising:
a radio-frequency (RF) antenna;
an RF receiver;
a baseband processor; and
an oscillator, the oscillator including:
a resonator configured to provide a periodic signal;
a circuit coupled to the resonator, the circuit configured to compensate for changes in the periodic signal due to variation in temperature; and
a heat source configured to generate heat that heats the resonator and the circuit, at least one of the resonator, circuit, and heat source embedded in a substrate, the resonator, circuit, and heat source arranged to heat the resonator and the circuit substantially the same by the heat source.

34. The portable device of claim 33, further comprising:
an RF transmitter.

35. The portable device of claim 33 wherein the circuit and the heat source comprise one integrated circuit.

36. The portable device of claim 35 wherein the one integrated circuit is embedded in a substrate.

37. The portable device of claim 33, further comprising a package coupled to a surface of the substrate, at least one of the resonator and the circuit disposed in the package, the resonator and the circuit arranged to receive substantially the same amount of heat from the heat source.

38. The portable device of claim 33 wherein the resonator, the circuit, and the heat source are embedded in the substrate.

39. A method of making an oscillator comprising:
receiving a first layer, the first layer having a first side and a second side, the first side having metal foil thereon;
coupling an electronic component to the second side of the first layer;
disposing a second layer around the electronic component, the second layer having an opening configured to fit around the electronic component;
disposing a third layer on the second layer, the third layer having a first side coupled to the third layer and a second side having a metal foil thereon;
bonding the first layer, the second layer, and the third layer together to form a substrate; and
coupling a resonator to the second side of the third layer, the resonator configured to provide a periodic signal.

40. The method of claim 39, wherein the electronic component comprises a circuit coupled to the resonator, and the circuit is configured to compensate for changes in the periodic signal due to variation in temperature.

41. The method of claim 39, further coupling a temperature compensation circuit to the resonator, the temperature compensation circuit configured to compensate for changes in the periodic signal due to variation in temperature and wherein the electronic component comprises an integrated circuit configured to generate heat.

42. A method of making an oscillator comprising:
receiving a first layer, the first layer having a first side and a second side, the first side having metal foil thereon;
coupling a plurality of electronic components to the second side of the first layer;
disposing a second layer around the plurality of electronic components, the second layer having a plurality of openings each configured to fit around a respective electronic component of the plurality of electronic components;
disposing a third layer on the second layer, the third layer having a first side coupled to the third layer and a second side having a metal foil thereon; and
bonding the first layer, the second layer, and the third layer together to form a substrate;
coupling a resonator to the second side of the third layer, the .

43. The method of claim 42, wherein the plurality of electronic components comprises a resonator configured to provide a periodic signal and a circuit coupled to the resonator, the circuit configured to compensate for changes in the periodic signal due to variation in temperature.

44. The method of claim 42, further wherein the plurality of electronic components comprises an integrated circuit configured to generate heat.
